(19) United States
(12) Patent Application Publication
(10) Pub. No.: US 2008/0042191 A1
(43) Pub. Date: Feb. 21, 2008

(54) NON-VOLATILE MEMORY DEVICE AND METHOD OF FABRICATING THE SAME

(75) Inventors: Cheng-Wei Lin, Hsinchu (TW); Kuang-Wen Liu, Hsinchu (TW); Hsin-Huei Chen, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/465,885

(22) Filed: Aug. 21, 2006

(51) Int. Cl. H01L 29/792; H01L 21/336

(52) U.S. Cl. 257/324; 438/287; 438/591; 438/954; 257/411

(57) ABSTRACT

A method of fabricating a non-volatile memory device is provided. The method includes forming a plurality of trenches in a substrate. The trenches are filled with first conducting layers to serve as buried bit lines. Thereafter, a charge storage layer is formed on the substrate to cover the surface of the substrate and the first conducting layers. A plurality of second conducting layers is formed on the charge storage layer to serve as word lines.

### BACKGROUND OF THE INVENTION

1. Field of the Invention

The present invention relates to a memory device and fabricating method thereof, and more particularly, to a non-volatile memory device and method of fabricating the same.

2. Description of Related Art

Non-volatile memory (“NVM”) refers to semiconductor memory which is able to continually store information even when the supply of electricity is removed from the device containing the NVM cell. NVM includes Mask Read-Only Memory (Mask ROM), Programmable Read-Only Memory (PROM), Erasable Programmable Read-Only Memory (EPROM), Electrically Erasable Programmable Read-Only Memory (EEPROM), and Flash Memory. Non-volatile memory is extensively used in the semiconductor industry and is a class of memory developed to prevent loss of programmed data. Typically, non-volatile memory can be programmed, read and/or erased based on the device's end-use requirements, and the programmed data can be stored for a long period of time.

As the information technology market has grown vastly in the past twenty years or so, portable computers and the electronic communications industry have become the main driving force for semiconductor VLSI (very large scale integration) and ULSI (ultra large scale integration) design. As a result, low power consumption, high density and re-programmable non-volatile memory are in great demand. These types of programmable and erasable memories have become essential devices in the semiconductor industry.

A rising demand for memory capacity has translated into higher requirements for integration level and memory density. Dual bit cells which can store two bits of information in each memory cell are known in the art but are not yet prevalent in use. One type of memory device having dual-bit cells is called a nitride read-only-memory. This is a type of charge trapping semiconductor device for data storage.

Nitride read only memory is a type of charge-trapping semiconductor device for data storage. In general, a nitride read-only-memory cell is composed of a MOSFET (metal-oxide-silicon field effect transistor) having an ONO (oxide-nitride-oxide) gate dielectric layer disposed between the gate and the source/drain semiconductor material. The nitride layer in the ONO gate dielectric layer is able to trap electrons in a localized manner when programmed. Charge localization refers to the nitride material's ability to store the charge without much lateral movement of the charge throughout the nitride layer. This is in contrast to conventional floating gate technology wherein the floating gate is conductive and the charge is spread laterally throughout the entire floating gate. Programming (i.e., charge injection) of the charge-trapping layer in a nitride read-only-memory devices can be carried out via channel hot electron (“CHE”) injection. Erasing (i.e., charge removal) in a nitride read-only-memory devices can be carried out via band-to-band hot hole tunneling. The stored charge can be repeatedly programmed, read, erased and/or reprogrammed via known voltage application techniques, and reading can be carried out in a forward or reverse direction. Localized charge-trapping technology allows two separate bits per cell, thus doubling memory density.

FIGS. 1A through 1C are schematic cross-sectional views showing the steps for fabricating a conventional a nitride read-only-memory. As shown in FIG. 1A, the method of fabricating the a nitride read-only-memory includes sequentially forming a nitride/oxide/nitride stack layer 102, a doped polysilicon layer 104 and a cap layer 106 over a substrate 100. Then, as shown in FIG. 1B, photolithographic and etching processes are performed to pattern the nitride/oxide/nitride stack layer 102, the doped polysilicon layer 104 and the cap layer 106 into a patterned nitride/oxide/nitride stack layer 102a, the doped polysilicon layer 104a and the cap layer 106a. Thereafter, an ion implant process is performed using the cap layer 106a as a mask to form doped regions 110 in the substrate 100 that serve as bit lines. Afterwards, a dielectric layer 112 is formed on the doped region 110 between the adjacent doped polysilicon layers 104.

Next, as shown in FIG. 1C, the cap layer 106a is removed. After that, a metal silicide layer 114 is formed over the substrate 100. Then, the metal silicide layer 114 and the doped polysilicon layer 104a are patterned to form the metal silicide layer 114 and a doped polysilicon layer 104b serving as a word line.

As shown in FIG. 1B, polymers 108 are likely formed in the foregoing etching process for forming the nitride/oxide/nitride stack layer 102a, the doped polysilicon layer 104a and the cap layer 106a. If the polymers 108 remain on the sidewalls of the nitride/oxide/nitride stack layer 102 and the doped polysilicon layer 104 as residue, the residue will be replaced by metal silicide in the subsequent deposition process for forming the metal silicide layer 114. Hence, the replaced metal silicide layer 114a will form a direct contact with the doped region 110 of the bit line and lead to a short circuit as shown in FIG. 1C.

On the other hand, as shown in FIGS. 2A and 2B, if the etching conditions for etching the nitride/oxide/nitride stack layer 102, the doped polysilicon layer 104 and the cap layer 106 are not properly controlled that the doped polysilicon layer 104a has an inverted trapezium shape, the etching of the doped polysilicon layer 104b will be incomplete in the subsequent process of forming the patterned metal silicide layer 114 and the doped polysilicon layer 104b. As a result, residual polysilicon stringers 120 are left on the sidewalls of the trapezium dielectric layer 112 so that the neighboring word lines are electrically connected.

### SUMMARY OF THE INVENTION

Accordingly, the present invention is to provide a non-volatile memory device and a fabricating method thereof that can prevent polymer residue from forming a direct contact between a word line and the doped region of a bit line that leads to a short circuit problem.

The present invention is also to provide a non-volatile memory device and a fabricating method thereof that can prevent residual polysilicon stringers from forming on the sidewalls of a dielectric layer due to the improper control of the etching conditions in a conventional process leading to the problem of an unwanted electrical connection between neighboring word lines.

To achieve these and other advantages and in accordance with the purpose of the invention, as embodied and broadly described herein, the invention provides a method of fabricating a non-volatile memory device. The method includes forming a plurality of trenches in a substrate. The trenches are filled with first conducting layers to serve as buried bit lines. Thereafter, a charge storage layer is formed on the substrate to cover the surface of the substrate and the first conducting layers. After that, a plurality of second conducting layers is formed on the charge storage layer to serve as word lines.

According to one embodiment of the present invention, the foregoing first conducting layers have dopants. Moreover, the foregoing method further includes diffusing a portion of the dopants in the first conducting layers into the surrounding substrate to form diffusion regions so that the diffusion regions and the foregoing first conducting layers together form the buried bit lines.

According to one embodiment of the present invention, the foregoing step of diffusing a portion of the dopants in the first conducting layers to the surrounding substrate is carried out at the same time as the step of forming the foregoing charge storage layer on the substrate.

According to one embodiment of the present invention, the method of forming the foregoing charge storage layer includes forming a bottom oxide layer on the substrate. Then, a nitride layer is formed on the bottom oxide layer. Finally, a top oxide layer is formed on the nitride layer.

According to one embodiment of the present invention, the foregoing bottom oxide layer/nitride layer/top oxide layer includes silicon oxide layer/silicon nitride layer/silicon oxide layer.

According to one embodiment of the present invention, the method of forming the foregoing first conducting layers includes depositing a polysilicon layer and performing an in-situ doping to form a doped polysilicon layer.

According to one embodiment of the present invention, the method of forming the second conducting layers includes forming a doped polysilicon layer on the charge storage layer and then forming a metal silicide layer on the doped polysilicon layer.

The present invention also provides a non-volatile memory device. The memory device includes a plurality of doped first conducting layers, a charge storage layer and a plurality of second conducting layers. The first conducting layers are buried within a substrate and fabricated using a material different from the substrate. The first conducting layers serve as buried bit lines. The charge storage layer directly covers the substrate and the first conducting layers. The second conducting layers directly cover the charge storage layer and serve as word lines.

According to one embodiment of the present invention, the foregoing non-volatile memory device further includes a plurality of diffusion regions in the substrate surrounding the first conducting layers. The diffusion regions and the foregoing first conducting layers together form a plurality of buried bit lines.

According to one embodiment of the present invention, the charge storage layer in the non-volatile memory device includes a bottom oxide layer on the substrate, a nitride layer on the bottom oxide layer and a top oxide layer on the nitride layer.

According to one embodiment of the present invention, the foregoing bottom oxide layer/nitride layer/top oxide layer includes silicon oxide layer/silicon nitride layer/silicon oxide layer.

According to one embodiment of the present invention, the foregoing doped first conducting layers include doped polysilicon layers.

According to one embodiment of the present invention, the foregoing word lines are not parallel to the bit lines and the second conducting layers include the doped polysilicon layer on the charge storage layer and the metal silicide layer on the doped polysilicon layer.

Because the bit lines in the present invention are formed in the substrate, there is no need to form conducting layers in the substrate to serve as word lines and use that as an implant mask to form the bit lines. Hence, residual polymers on the sidewalls of the conducting layers due to etching in a conventional process, which can lead to a direct contact between the metal silicide layer of the word lines and the diffusion regions of the bit lines and hence a short circuit, can be avoided. Furthermore, the present invention can prevent residual polysilicon stringers from forming on the sidewalls of a dielectric layer due to the improper control of the etching conditions in a conventional process and hence prevent the problem of having an unwanted electrical connection between neighboring word lines.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are schematic cross-sectional views showing the steps for fabricating a conventional a nitride read-only-memory.

FIG. 2A is a perspective view of a portion of a conventional a nitride read-only-memory.

FIG. 2B is a schematic cross-sectional view along line II-II of FIG. 2A.

FIGS. 3A through 3F are schematic cross-sectional views showing the steps for fabricating a non-volatile memory device according to one embodiment of the present invention.

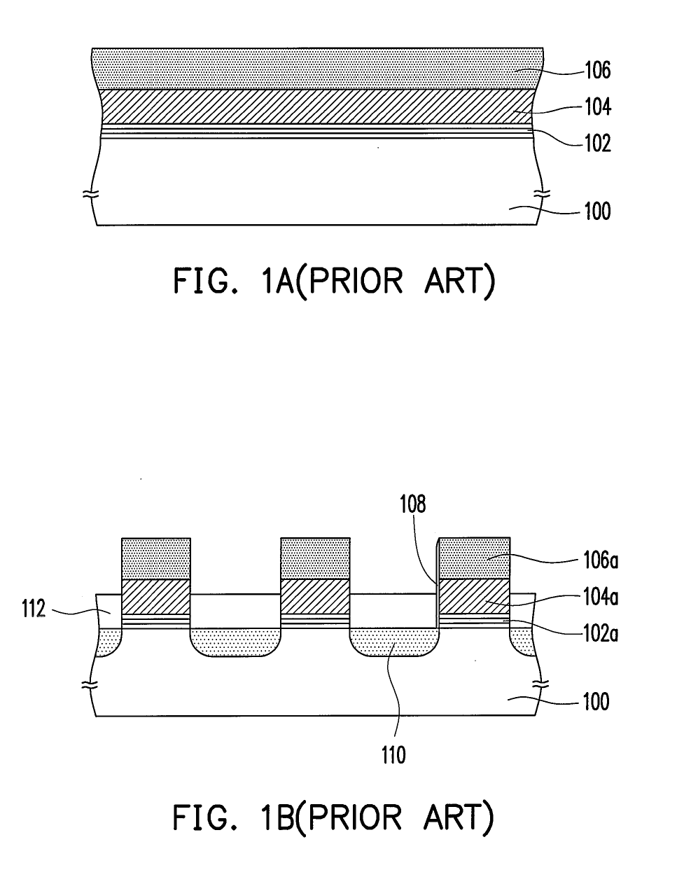

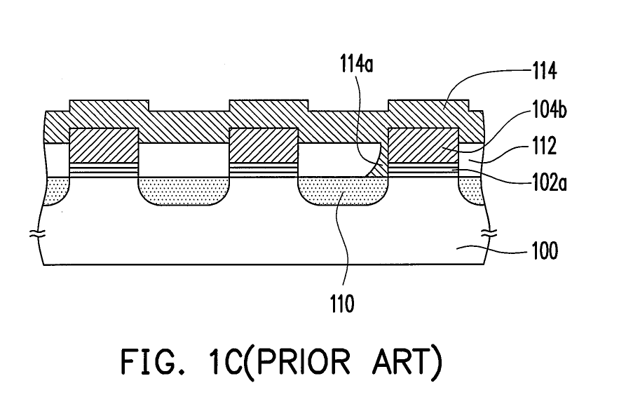

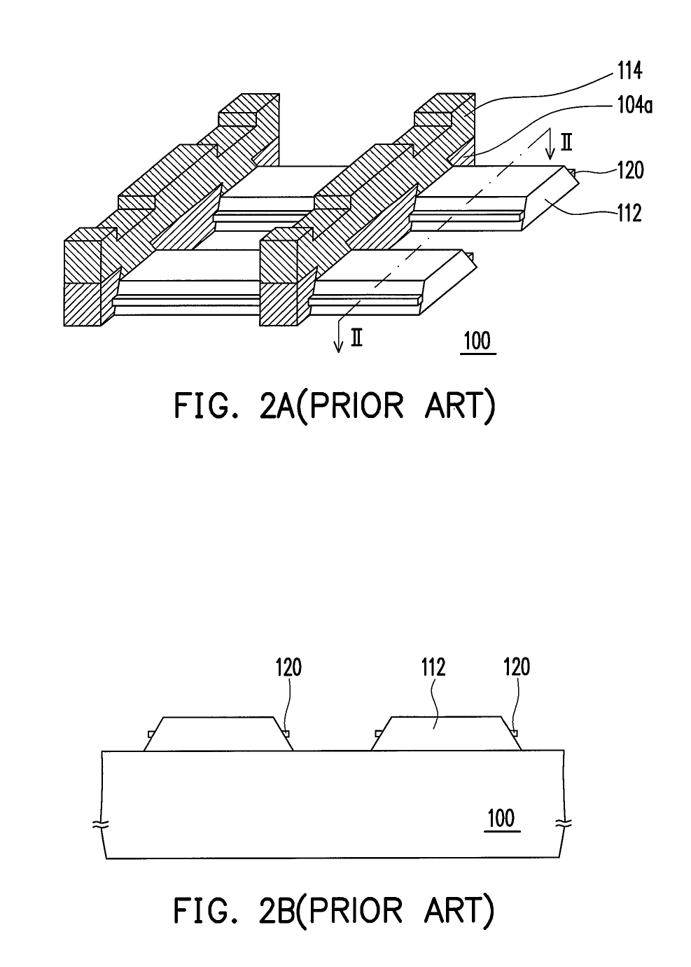

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

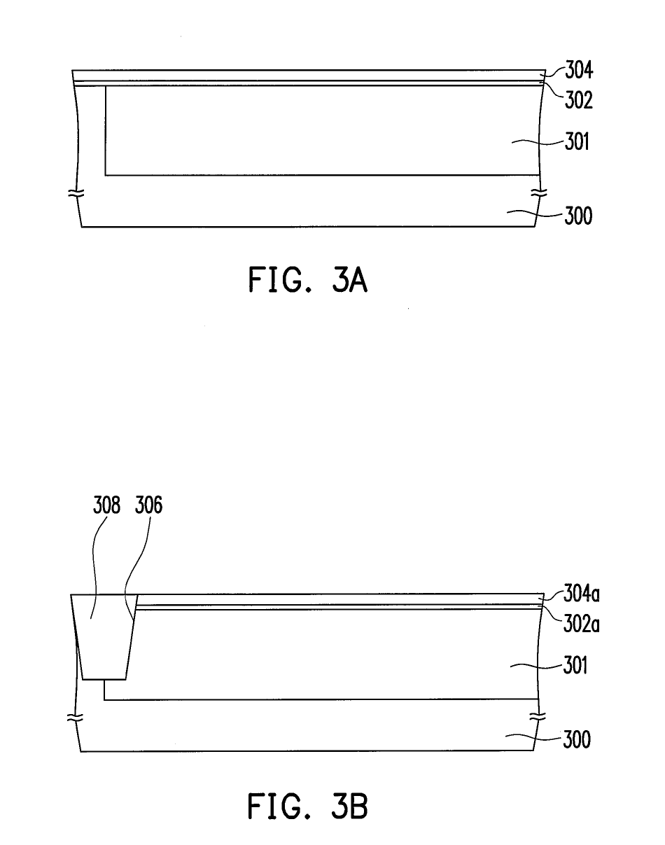

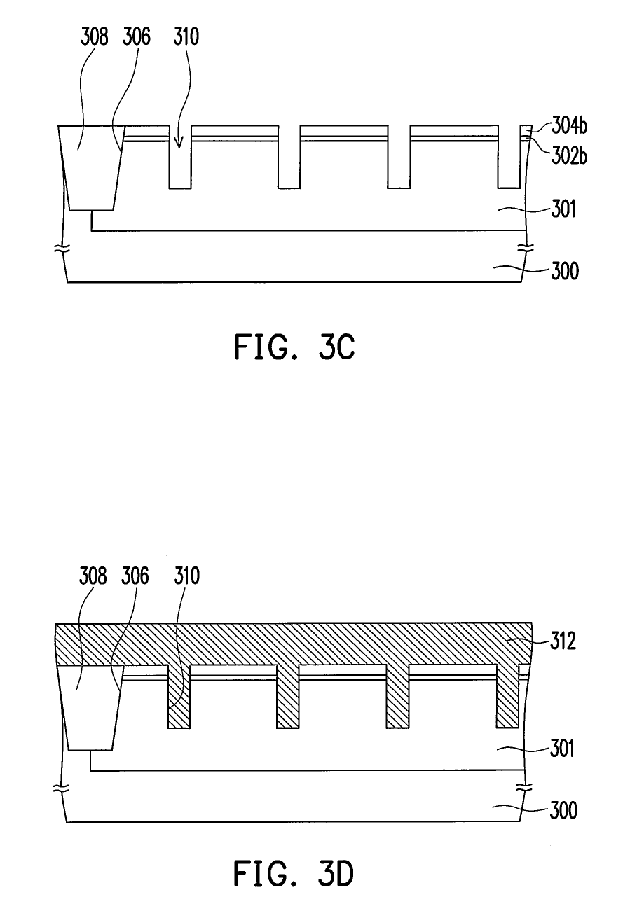

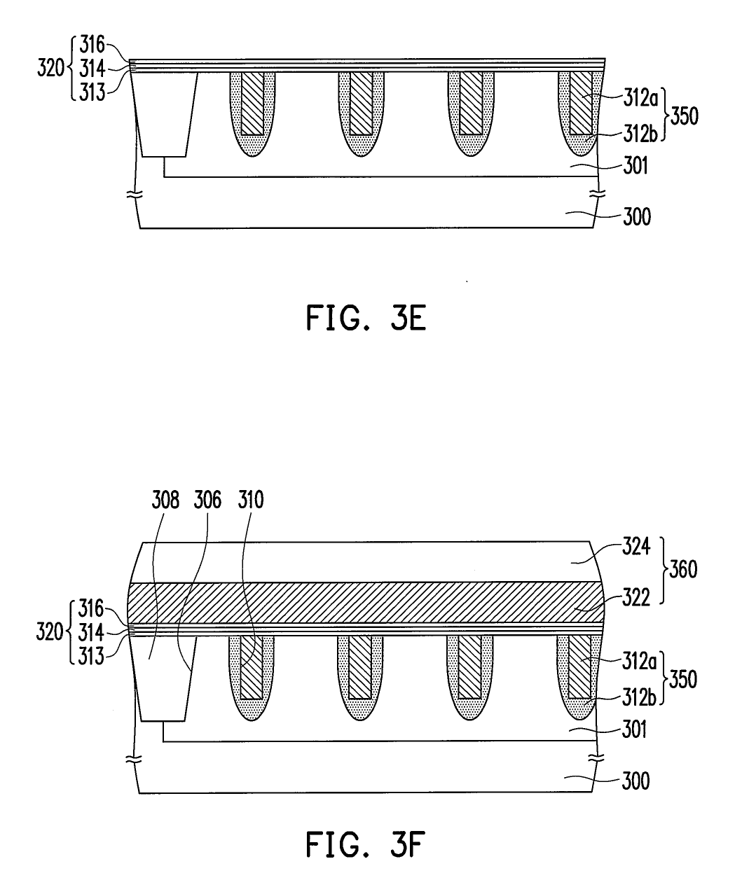

FIGS. 3A through 3F are schematic cross-sectional views showing the steps for fabricating a non-volatile memory device according to one embodiment of the present invention.

As shown in FIG. 3A, a substrate 300 is provided. The substrate 300 is fabricated using a semiconductor material such as silicon or germanium. In one embodiment, the substrate 300 is a silicon bulk. In another embodiment, the substrate 300 is a silicon-on-insulation (SOI) layer. Then, a well region 301 is formed in the substrate 300. If the substrate 300 is n-doped, the well region 301 is p-doped. On the other hand, if the substrate is p-doped, the well region 301 is n-doped. Thereafter, a mask layer 304 is formed on the substrate 300. The mask layer 304 is a silicon nitride layer formed, for example, by performing a chemical vapor deposition process. Preferably, a pad oxide layer 302 is formed before the silicon nitride layer. The method of forming the pad oxide layer 302 includes, for example, performing a thermal oxidation.

As shown in FIG. 3B, photolithographic and etching processes are performed to pattern the mask layer 304 into a mask layer 304a. Then, the pad oxide layer 302 and the substrate 300 are etched using the mask layer 304a as a hard mask to form a shallow trench 306 in the substrate 300. Thereafter, an insulating layer is formed in the shallow trench 306 to form a shallow trench isolation (STI) structure 308.

As shown in FIG. 3C, another photolithographic and etching processes are performed to pattern the mask layer 304a into a mask layer 304b. Then, the pad oxide layer 302a and the substrate 300 are etched using the mask layer 304b as a hard mask to form trenches 310 in the substrate 300. The pad oxide layer 302a and the substrate 300 can be etched by performing an anisotropic etching process using a fluoride compound such as carbon tetra-fluoride (CF₄) or sulfur hexa-fluoride (SF₆) as the gaseous etchant.

As shown in FIG. 3D, a doped conducting layer 312 is formed over the substrate 300 to cover the mask layer 304b and fill the trenches 310. The doped conducting layer 312 is, for example, a doped polysilicon layer. If the well region 301 is p-doped, the conducting layer 312 is an n-doped polysilicon layer, for example. On the other hand, if the well region 301 is n-doped, the conducting layer 312 is a p-doped polysilicon layer, for example. The method of forming the doped polysilicon layer includes, for example, performing a chemical vapor deposition process to deposit polysilicon and performing an in-situ doping at the same time.

As shown in FIG. 3E, the conducting layer 312 outside the trenches 310 is removed. The method of removing the conducting layer 312 outside the trenches 310 includes performing a chemical-mechanical polishing using the mask layer 304b as a polishing stop layer. After removing the redundant conducting layer 312, the conducting layers 312a that remain in the trenches 310 serve as part of the buried bit lines. Afterwards, the mask layer 304b and the pad oxide layer 302b are removed to expose the surface of the substrate 300. Then, a charge storage layer 320 is formed on the surface of the substrate 300. In one embodiment, the charge storage layer 320 comprises a bottom oxide layer 313, a nitride layer 314 and a top oxide layer 316. For example, a thermal oxidation process is performed to form a silicon oxide layer on the substrate 300. Then, a chemical vapor deposition process is performed to form a nitride layer on the silicon oxide layer. Finally, a wet thermal oxidation process is performed to form another silicon oxide layer on the nitride layer. In the process of forming the charge storage layer 320, the heat may drive the dopants in the conducting layers 312a within the trenches 310 to diffuse into the substrate 300 surrounding the trenches 310, thereby forming a plurality of diffusion regions 312b. The diffusion regions 312b and the conducting layers 312a together form the buried bit lines 350 of the memory device in the present invention.

As shown in FIG. 3F, a patterned conducting layer 360 is formed over the substrate to serve as a word line. The word lines are not parallel to the bit lines. The conducting layer 360 comprises, for example, a doped polysilicon layer 322 and a metal silicide layer 324. The material constituting the metal silicide layer 324 includes tungsten silicide, for example.

Because the bit lines in the present invention are formed in the substrate, there is no need to form conducting layers in the substrate to serve as word lines and use that as an implant mask to form the bit lines. Hence, residual polymers on the sidewalls of the conducting layers due to etching in a conventional process, which can lead to a direct contact between the metal silicide layer of the word lines and the diffusion regions of the bit lines and hence a short circuit, can be avoided. Furthermore, the present invention can prevent residual polysilicon stringers from forming on the sidewalls of a dielectric layer due to the improper control of the etching conditions in a conventional process and hence prevent the problem of having an unwanted electrical connection between neighboring word lines.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a non-volatile memory device, comprising:
forming a plurality of trenches in a substrate;
forming a first conducting layer inside the trenches to serve as buried bit lines;
forming a charge storage layer over the substrate to cover the surface of the substrate and the first conducting layers; and
forming a plurality of second conducting layers on the charge storage layer to serve as word lines.

2. The method of claim 1, wherein the first conducting layers have dopants, and the method further comprising diffusing a portion of the dopants in the first conducting layers into the substrate surrounding the first conducting layers to form a plurality of diffusion regions so that the diffusion regions and the first conducting layers together form the buried bit lines.

3. The method of claim 2, wherein the step of diffusing a portion of the dopants in the first conducting layers into the substrate surrounding the first conducting layers is performed at the same time as the step of forming the charge storage layer on the substrate.

4. The method of claim 1, wherein the method of forming the charge storage layer comprises:
forming a bottom oxide layer on the substrate;
forming a nitride layer on the bottom oxide layer; and
forming a top oxide layer on the nitride layer.

5. The method of claim 1, wherein the bottom oxide layer, the nitride layer and the top oxide layer of the charge storage layer are a silicon oxide layer, a silicon nitride layer and a silicon oxide layer.

6. The method of claim 1, wherein the method of forming the doped first conducting layers comprises depositing polysilicon and performing an in-situ doping process at the same time to form a doped polysilicon layer.

7. The method of claim 1, wherein the method of forming the second conducting layers comprises:
forming a doped polysilicon layer on the charge storage layer; and
forming a metal silicide layer on the doped polysilicon layer.

8. A non-volatile memory device, comprising:
a plurality of doped first conducting layers buried within a substrate, wherein the material constituting the doped first conducting layers is different from the material of the substrate, and the doped first conducting layers are used as buried bit lines;
a charge storage layer, directly covering the substrate and the doped first conducting layers; and
a plurality of second conducting layers, directly covering the charge storage layer to serve as word lines.

9. The non-volatile memory device of claim 8, wherein the word lines are not parallel to the bit lines.

10. The non-volatile memory device of claim 8, further comprising a plurality of diffusion regions located in the substrate surrounding the doped first conducting layers so that the diffusion regions and the first conducting layers together form the buried bit lines.

11. The non-volatile memory device of claim 8, wherein the charge storage layer comprises:
a bottom oxide layer, disposed on the substrate;
a nitride layer, disposed on the bottom oxide layer; and
a top oxide layer, disposed on the nitride layer.

12. The non-volatile memory device of claim 11, wherein the bottom oxide layer, the nitride layer and the top oxide layer in the charge storage layer are a silicon oxide layer, a silicon nitride layer and a silicon oxide layer.

13. The non-volatile memory device of claim 8, wherein the doped first conducting layers are doped polysilicon layers.

14. The non-volatile memory device of claim 8, wherein each of the second conducting layers comprises:
a doped polysilicon layer, disposed on the charge storage layer; and
a metal silicide layer, disposed on the doped polysilicon layer.
